(19) United States
(12) Patent Application Publication
(10) Pub. No.: US 2009/0028277 A1
(43) Pub. Date: Jan. 29, 2009

(54) Method and system for denoising noisy signals

(76) Inventor: Itschak Weissman, Menlo Park, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/881,512

(22) Filed: Jul. 27, 2007

(51) Int. Cl. H04B 1/10; H03D 1/04; H04L 1/00; H04L 25/08

(52) U.S. Cl. 375/346

(57) ABSTRACT

Embodiments of the present invention are directed to generally applicable denoising methods and systems for recovering, from a noise-corrupted signal, a cleaned signal equal to, or close to, the original, clean signal that suffered corruption due to one or more noise-inducing processes, devices, or media In a first pass, method embodiments and system embodiments of the present invention receive an instance of one of many different types of neighborhood rules and use the received neighborhood rule to acquire statistics from a noisy signal. In a second pass, the method embodiments and system embodiments of the present invention receive an instance of one of many different types of denoising rules, and use the received denoising rule to denoise a received, noisy signal in order to produce a cleaned signal.

### TECHNICAL FIELD

The present invention is related to data processing and signal processing and, in particular, to a general, widely applicable method and system for denoising signals corrupted by noise.

### BACKGROUND OF THE INVENTION

Many different techniques are currently applied, in many different applications, computational environments, system environments, and problem domains for denoising noise-corrupted signals. For example, in many communications systems, transmission of a digitally encoded signal through a noise-inducing channel results in a potentially noise-corrupted signal to which denoising methods are applied in order to reproduce, as closely as possible, the original digitally encoded signal submitted for transmission through the noise-inducing channel. Noise-inducing channels may include electronic communications media, many different types of computational processes, and a wide variety of different types of data-storage, data-rendering, data-transmission, data-acquisition, and data-processing devices. As one example, data stored in an electronic memory may suffer corruptions from cosmic radiation, discharge of static electricity, and voltage fluctuations on signal lines input to the electronic memory. Data retrieved from the electronic memory may, as a result, differ from the data originally submitted to the electronic memory for storage. As another example, data transmitted through an electronic communications medium may be corrupted by electronic interference from neighboring communications channels, sporadic failures in repeaters and other hardware components of the communications medium, and by many other types of noise-introducing events. As a result, the signal received at a destination receiver may differ significantly from the signal originally input, via a transmitter, to the communications medium.

Noise-inducing channels may, however, include a great many other types of phenomena that transform or change information. For example, changes in the nucleotide sequence of a gene due to random processes may be viewed as noise introduced into signals comprising ancestral DNA sequences, and subtle changes in the three-dimensional conformation of a protein that result from changes in the gene encoding the protein, or even changes in related regulatory regions of a chromosome containing the gene, may be viewed as resulting from noise introduced into the chromosome nucleotide sequence containing the gene encoding the protein. Many types of data collected from scientific and economic observations may also be regarded as information encoded as a sequence of symbols that differs from a sequence of symbols that would be expected or desired as a result of noise introduced by recording observations, by observational methods, and by encoding and storing observed events. The phrase “noise-corrupted” does not necessarily imply that the noise-intruding processes are unnatural or represent a degradation or deterioration of a signal, but only that an initial signal has been somehow altered or transformed. In the case of genomic changes due to random processes, the alterations may be quite favorable for an organism carrying the altered gene sequence. For example, a bacterial host may carry mutations, considered as noise with respect to an ancestral sequence, that allow the bacterial host to survive antibacterial chemical treatments, antibiotics, and infection by phage.

Many different techniques are employed to recognize and address the many sources of noise encountered in different types of signals and signal-transmitting devices and media. For example, error-correcting codes may be employed to detect and recover from certain types of data and signal corruption, using redundant information stored in the signal for both error detection and error correction. In addition, many signal-transmission-related protocols, data-storage formatting conventions, and other signal-encoding conventions are designed to ameliorate the overall effects of noise introduced into signals, so that the effects of a given error are locally contained, and do not therefore lead to corruption of the entire signal. As one example, MPEG encoding of video signals employs frequent transmission of reference frames, without dependencies on previous or subsequent frames, which serve as reference points for the more complex, temporally encoded frames transmitted between reference frames. Errors in one or more temporally encoded frames therefore impact only a subsequence of frames up to the next, transmitted reference frame, rather than potentially impacting all subsequent frames. Other techniques rely on knowledge, at a signal destination or signal-recovery point, of certain characteristics of the originally transmitted signal in order to infer which portions of a received or recovered signal may be corrupted, as well as to infer corrections that can be applied to the received or recovered signal in order to produce a signal as close as possible to the originally transmitted or stored signal.

Many denoising techniques are algorithmically complex, and may be computationally intractable when applied to particular problem domains, particularly real-time problem domains. Many denoising techniques may be applicable to only a relatively small subset of the many types of denoising-related problem domains to which denoising methods and systems are applied, and the criteria for determining the applicability of a particular denoising method may be complex. For these reasons, information scientists, computer scientists, and designers, vendors, and users of a wide variety of different information-transmission media, processes, devices, and information-processing software and hardware continue to recognize a need for simple, computationally efficient, and generally applicable denoising methods.

### SUMMARY OF THE INVENTION

Embodiments of the present invention are directed to generally applicable denoising methods and systems for recovering, from a noise-corrupted signal, a cleaned signal equal to, or close to, the original, clean signal that suffered corruption due to one or more noise-inducing processes, devices, or media In a first pass, method embodiments and system embodiments of the present invention receive an instance of one of many different types of neighborhood rules and use the received neighborhood rule to acquire statistics from a noisy signal. In a second pass, the method embodiments and system embodiments of the present invention receive an instance of one of many different types of denoising rules, and use the received denoising rule to denoise a received, noisy signal in order to produce a cleaned signal.

### BRIEF DESCRIPTION OF THE DRAWINGS

FIG. 1 illustrates one general problem domain, and notation conventions associated with the general problem domain, to which method embodiments and system embodiments of the present invention are directed.

FIGS. 2A-C illustrate a number of different neighborhoods defined with respect to a particular symbol S_{c} of a symbol sequence S.

FIGS. 3A-B illustrate higher-order organizations of the symbols within linear symbol sequences.

FIGS. 4A-D illustrate the four neighborhoods shown in FIGS. 3A-B when the symbol sequences are represented as one-dimensional, linear sequences.

FIGS. 5A-6C illustrate generation of a third-order neighborhood from a first-order neighborhood.

FIG. 7 illustrates neighbor pairs.

FIGS. 8 and 9 illustrate the general denoising method used by system embodiments of the present invention and to which method embodiments of the present invention are directed.

### DETAILED DESCRIPTION OF THE INVENTION

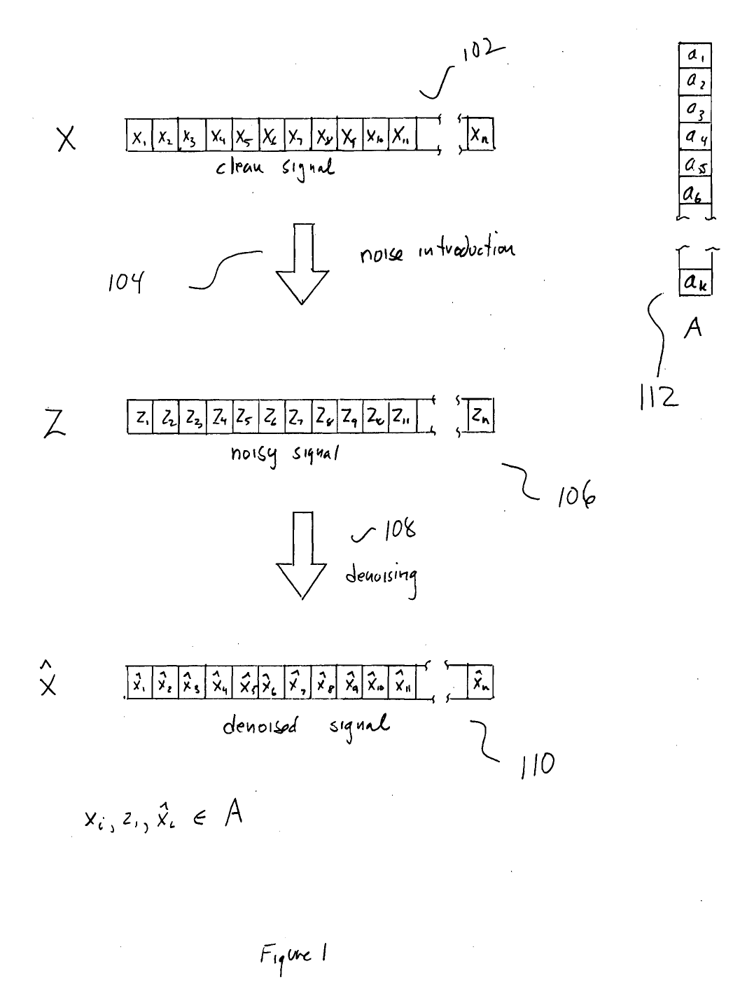

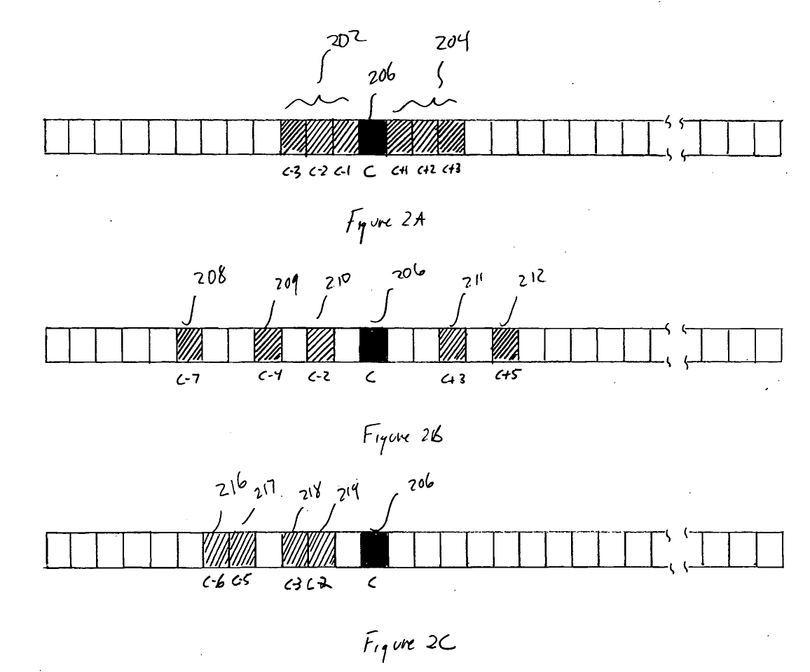

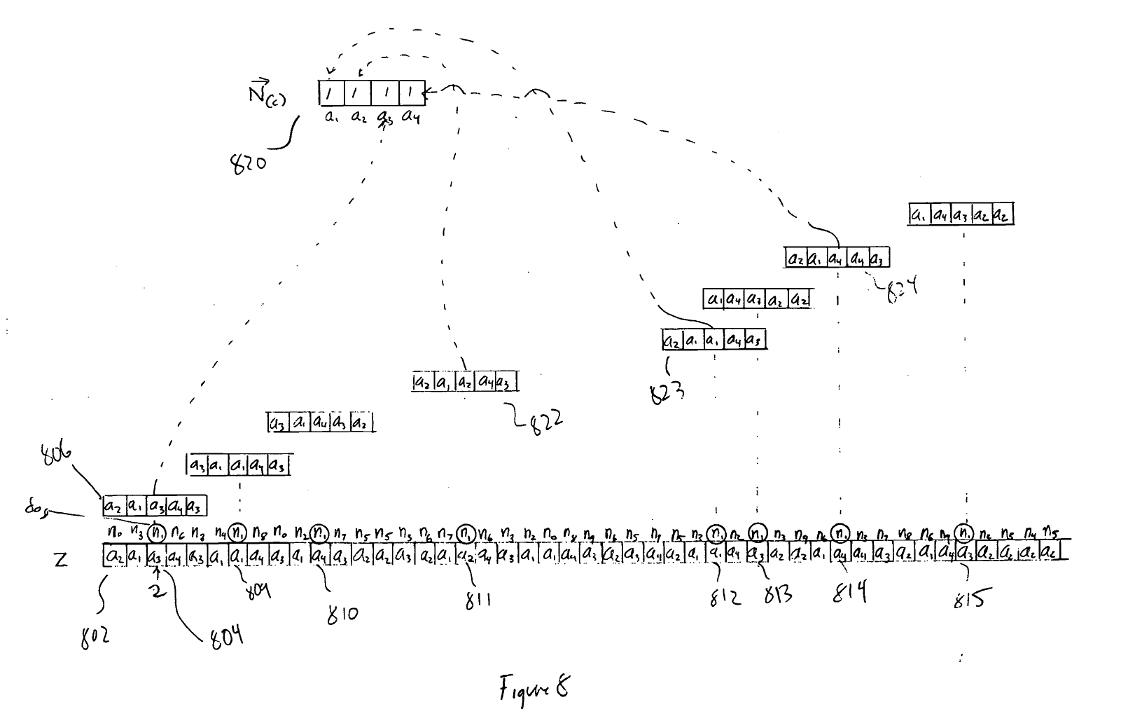

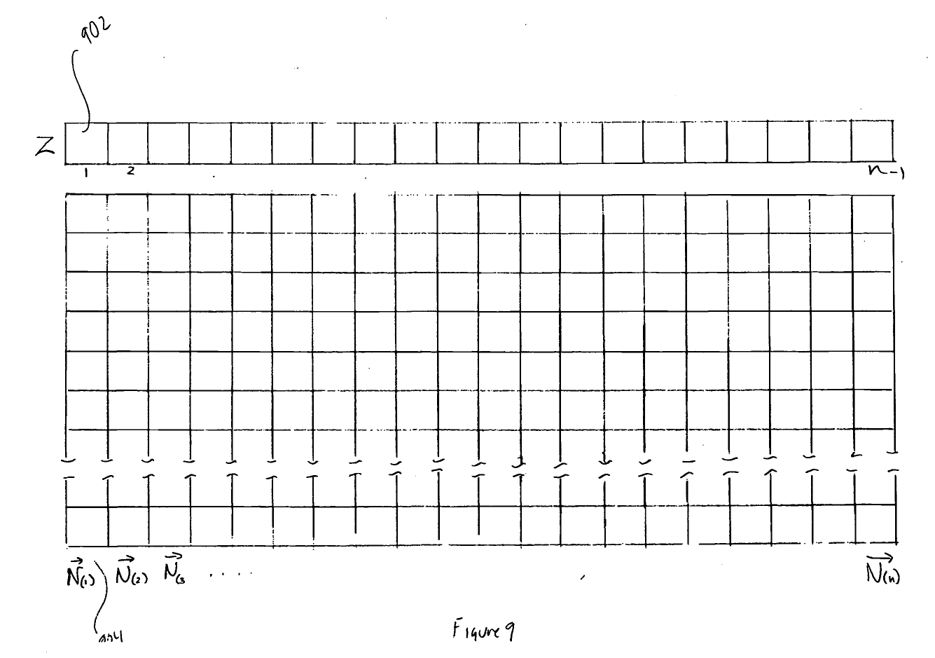

Embodiments of the present invention are directed to a large family of relatively straightforward, often computationally efficient, and widely applicable denoising methods and systems that share a common computational framework. In a first subsection, below, the general problem domain, and notation conventions associated with the problem domain, are discussed with reference to FIG. 1. In a next subsection, the concept of neighborhoods and neighborhood structure are discussed with reference to FIGS. 2A-7. In a third subsection, neighborhood-based statistics acquisition is discussed with reference to FIGS. 8-9. In a fourth subsection, a C++-like pseudocode implementation of one method embodiment of the present invention is provided. Finally, in a fifth subsection, a variety of different applications of the present invention to particular problem domains are discussed.

### General Problem Domain

FIG. 1 illustrates one general problem domain, and notation conventions associated with the general problem domain, to which method embodiments and system embodiments of the present invention are directed. It should be noted that a very large number of different types of specific problems may be cast within the general problem domain presented in this subsection, and that there are even more general problem domains that include this described problem domain as a special case. First, a clean signal 102, essentially a vector, or one-dimensional array, X of symbols, is subject to some type of noise-introducing process, medium, or device 104. Noise introduction results in a noisy signal 106, represented as a second vector Z of symbols. Then, one of many particular denoising methods or systems that fall within the scope of the current invention are applied 108 to the noisy signal Z to produce a denoised, or cleaned, signal 110, represented as a third vector \hat{X} of symbols. Each of the signals X, Z, and \hat{X} comprise an ordered sequence of symbols, each symbol selected from a known, fixed-length alphabet A 112 of cardinality |A|=k. Thus:

A=[a₁,a₂, . . . ,aₖ]

X=[x₁,x₂, . . . ,xₙ] where Xᵢ ε A

Z=[z₁,z₂, . . . ,zₙ] where Zᵢ ε A

X=[x₁,x₂, . . . ,\hat{x}ₙ] where \hat{X}ᵢ ε A

In many embodiments of the present invention, the lengths of all three signals X, Z, and \hat{X} are all equal to a single fixed integer n. Thus, many embodiments of the present invention are directed to denoising problems in which symbols of a clean signal are transformed into symbols of a noisy signal, and certain symbols of the noisy signal are transformed, by a denoising process, into corresponding symbols of a denoised signal. The symbol-transformation processes are closed, so that both noise-inducing symbol transformations and denoising symbol transformations produce valid symbols selected from alphabet A. Additionally, in the problem domains to which many embodiments of the present invention are applied, symbols are neither lost nor added during both the noise-inducing process and during the denoising process. In certain other problem domains, either or both of the closed-transformation and no-symbol-loss-or-addition constraints may be relaxed. In a still more general problem domain, the clean signal, noisy signal, and denoised signals X, Z, and \hat{X} may contain symbols selected from two or three alphabets, rather than a single alphabet, with the two or three alphabets either entirely distinct from one another or overlapping and having potentially different cardinalities. Thus, in the more general case:

A₁=[a₁₁,a₁₂, . . . ,a₁ₖ]

A₂=[a₂₁,a₂₂, . . . ,a₂ₗ]

A₃=[a₃₁,a₃₂, . . . ,a₃ₘ]

|A₁|=k

|A₂|=l

|A₃|=m

X=[x₁,x₂, . . . ,xₙ] where Xᵢ ε A₁

Z=[z₁,z₂, . . . ,zₙ] where Zᵢ ε A₂

X=[x₁,x₂, . . . . ,\hat{x}ₙ] where \hat{X}ᵢ ε A₃

### Neighborhoods and Neighborhood Structures

FIGS. 2A-C illustrate a number of different neighborhoods defined with respect to a particular symbol S_{c} of a symbol sequence S. FIG. 2A shows a symmetric, dense neighborhood 202 and 204 with respect to symbol S_{c} 206. A neighborhood is a set of one or more positions within a symbol sequence defined, by a neighborhood rule, as neighborhood positions relative to a particular, neighborhood-defining position. A neighborhood rule may be applied to any particular symbol position c in a symbol sequence to generate the neighborhood positions N(c) with respect to the neighborhood-defining symbol position. FIG. 2B shows a non-symmetric, sparse neighborhood 208-212 defined with respect to symbol Sc 206. FIG. 2C shows yet another neighborhood 216-219 about symbol Sc 206.

A neighborhood rule, applied to a particular symbol position within a symbol sequence, may generate a set of 0, 1, . . . , nMax symbol positions relative to the symbol to which the neighborhood rule is applied, where nMax is the maximum number of neighborhood positions generated by the neighborhood rule. Under certain definitions, a neighborhood rule may always generate the fixed number nMax of neighborhood positions, while, under other definitions, the number of positions generated by a neighborhood rule in a neighborhood N(c), relative to a neighborhood-defining position c, may vary. A neighborhood rule may be a deterministic algorithm or parameterized equation, or, alternatively, may simply be a list of indices, or positions, relative to the index or position of the neighborhood-defining symbol position within a symbol sequence. Thus, for example, the neighborhood rule for generating the neighborhood shown in FIG. 2A may be alternatively expressed as:

N_{(Sc)}={Sᵢ:|i−c|≦3}

N_{(Sc)}={c−3, c−2, c−1, c+1, c+2, c+3}

char NSc[6];

for (int i=0; i<3; i++)NSc[i]=i−3;

for (i=3; i<6; i++)NSc[i]=i−2;

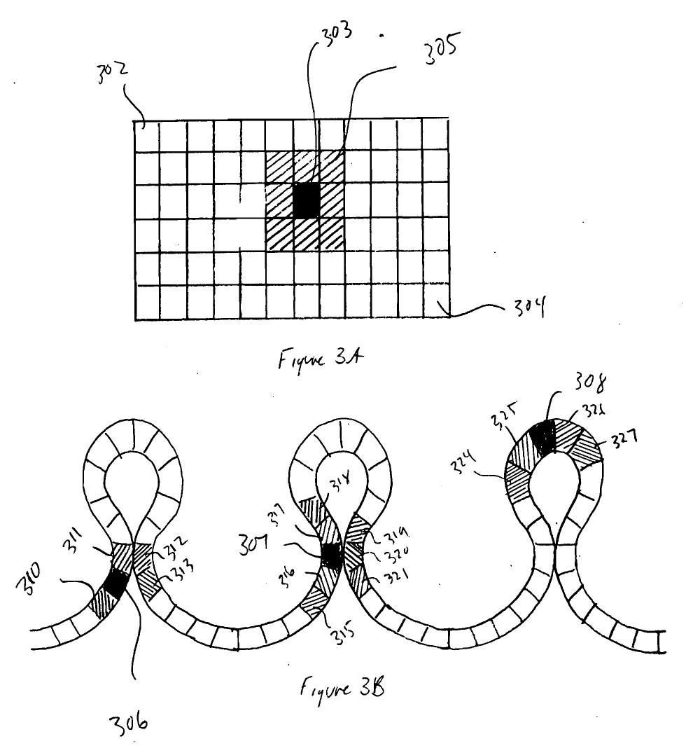

While the sparse and asymmetrical neighborhoods shown in FIGS. 2B-C may appear arbitrary, and while arbitrarily defined neighborhoods may prove useful in certain denoising problem domains, often such seemingly arbitrarily defined neighborhoods may, in fact, arise from higher-order considerations. FIGS. 3A-B illustrate higher-order organizations of the symbols within linear symbol sequences. In FIG. 3A, a linear symbol sequence is folded repeatedly back onto itself to form a rectangular region, with the first symbol of the sequence 302 at the upper left-hand corner of the rectangle and the final symbol of the sequence 304 at the bottom right-hand corner of the rectangle. Thus, the linear symbol sequence may be alternatively viewed as a two-dimensional rectangular array of symbols. Assuming indices starting from zero, the transformation S₍ᵢ₎→S_{(j,k)} from a one-dimensional, linear symbol sequence S₍ᵢ₎ to a two-dimensional rectangular symbol matrix S_{(j,k)} is provided by:

j=i MOD M;

k=i/M;
where M=row length of S_{(j,k)}
   A neighborhood-defining location 303 in the two-dimensional matrix of symbols may be associated with, as one example, a neighborhood comprising the eight nearest-neighbor symbols in the two-dimensional matrix, shown in FIG. 3A as a square region of crosshatching 305 surrounding the neighborhood-defining position 303.

FIG. 3B shows a more complex higher-level ordering of symbols within a linear symbol sequence. In FIG. 3B, the linear symbol sequence is, at a higher level, considered to be a repeated looping structure. Three neighborhood-defining positions 306-308 are shown in FIG. 3B as shaded positions of the sequence, while neighborhoods about these three neighborhood-defining positions are shown as crosshatched positions 310-313, 316-321, and 324-327, respectively.

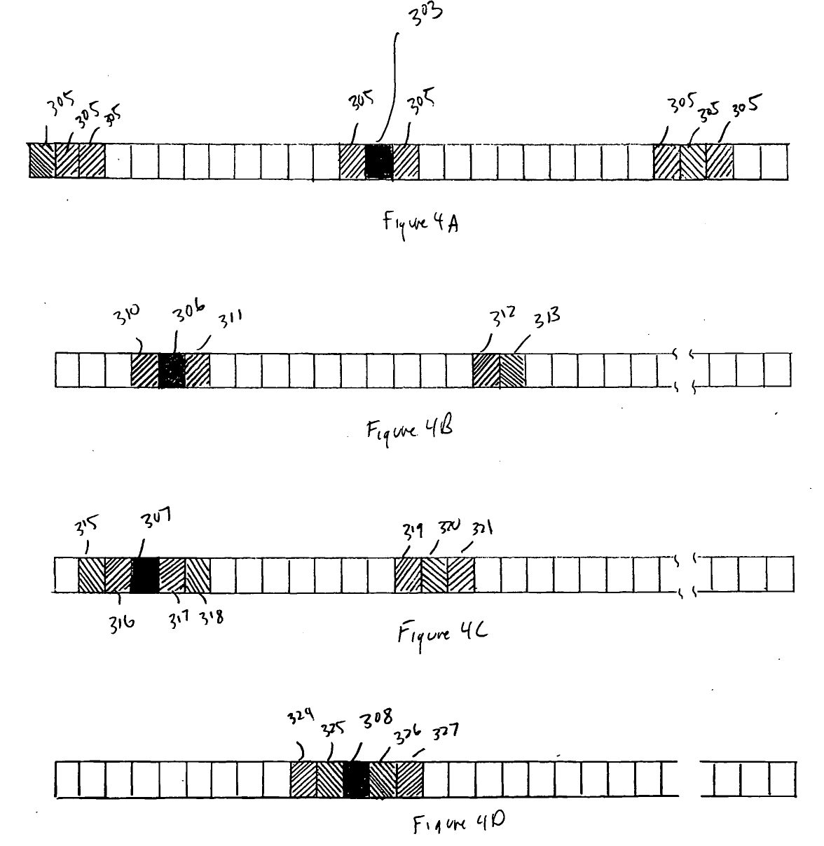

FIGS. 4A-D illustrate the four neighborhoods shown in FIGS. 3A-B when the symbol sequences are represented as one-dimensional, linear sequences. FIG. 4A, for example, shows the neighborhood 305 about neighborhood-defining position 303. FIGS. 4B-D show the neighborhoods about positions 306-308 in FIG. 3B. When viewed in the one-dimensional, linear representations shown in FIGS. 4A-D, the neighborhoods may appear to be somewhat arbitrary.

The two-dimensional symbol matrix shown in FIG. 3A may arise, for example, in a denoising problem related to photographic images or other two-dimensional matrices of symbols. The repeated loop structure shown in FIG. 3B may arise in denoising problems associated with the three-dimensional, secondary structure of proteins, nucleic acids, or other polymers that may be presented as one-dimensional linear sequences of monomer identifiers. There are a wide variety of different types of higher-level structures and orderings of linear symbol sequences that naturally follow from particular problem domains and symbolic representations of different types of data, including, in biological polymer-sequence data, neighborhoods related to secondary, tertiary, and quaternary structure.

While the neighborhood examples provided in FIGS. 4A-D are generated from high-order distance metrics, neighborhood rules may be based on non-distance-related metrics. For example, neighborhoods may be defined by periodic functions, by temporal relationships in time-ordered symbol sequences, and by an almost limitless number of alternative considerations.

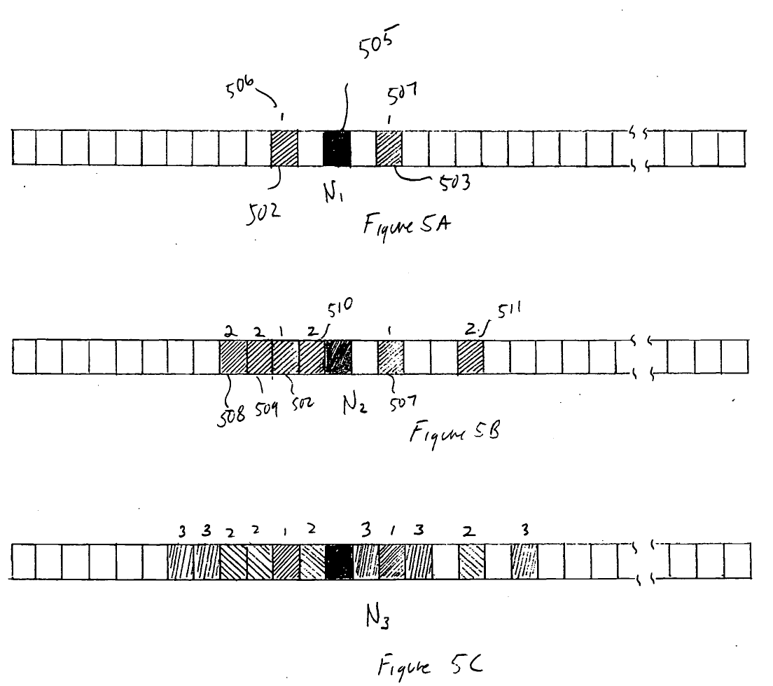

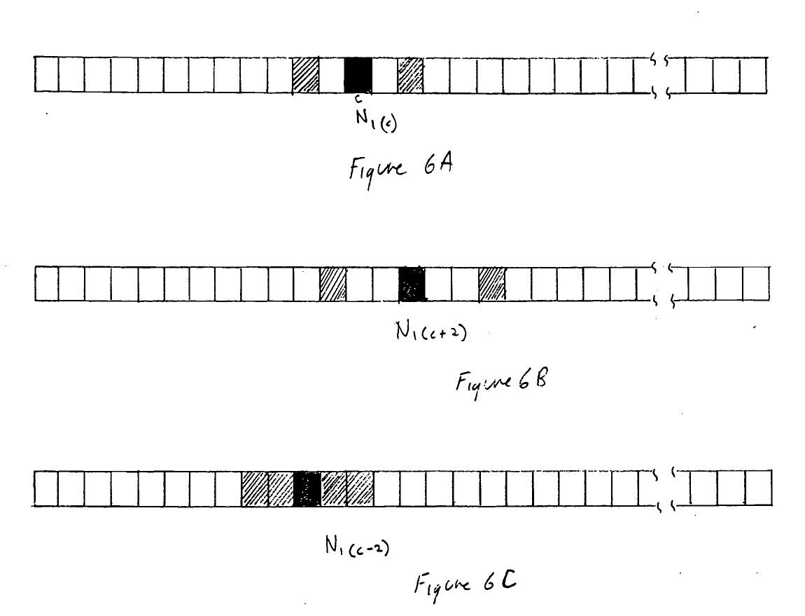

FIGS. 2A-C and 4A-D illustrate first-order neighborhoods. Higher-order neighborhoods may be iteratively or recursively generated from first-order neighborhoods. FIGS. 5A-6C illustrate generation of a third-order neighborhood from a first-order neighborhood. FIG. 5A shows a simple first-order neighborhood N₁ 502-503 with respect to a neighborhood-defining position 505. In FIG. 5A, the neighborhood positions 502 and 503 are marked by the symbols “1” 506-507 to indicate that the positions correspond to the first-order neighborhood about neighborhood-defining position 502. FIG. 6A illustrates the neighborhood rule used to generate the first-order neighborhood 502 and 503 shown in FIG. 5A.

In order to generate the second-order neighborhood N₂, shown in FIG. 5B, the neighborhood rules shown in FIGS. 6B and 6C for positions 503 and 502 in FIG. 5A, respectively, are applied to positions 503 and 502 in order to generate the neighborhood positions corresponding to the first-order neighborhood positions generated by application of the neighborhood rule, shown in FIG. 6A, to the neighborhood-defining position 505 in FIG. 5A. These new, second-order positions are added to the first-order positions 502 and 503 in FIG. 5A, to generate the second-order neighborhood 502, 507, and 508-511 shown in FIG. 5B. Newly generated, second-order positions that overlap the neighborhood-defining position 505 are not included in the second-order neighborhood, and the positions within a neighborhood are unique, so that higher-order positions that overlap lower-order positions do not generate additional positions within the higher-order neighborhood. FIG. 5C illustrates a third-order neighborhood obtained by applying the neighborhood rule shown in FIG. 6A to all of the second-order positions 508-511 shown in FIG. 5B. Thus, the l^{th}-order neighborhood Nₗ(i) for a sequence position i is generated by successively generating the first through (l−1)^{th}-order neighborhoods of position i.

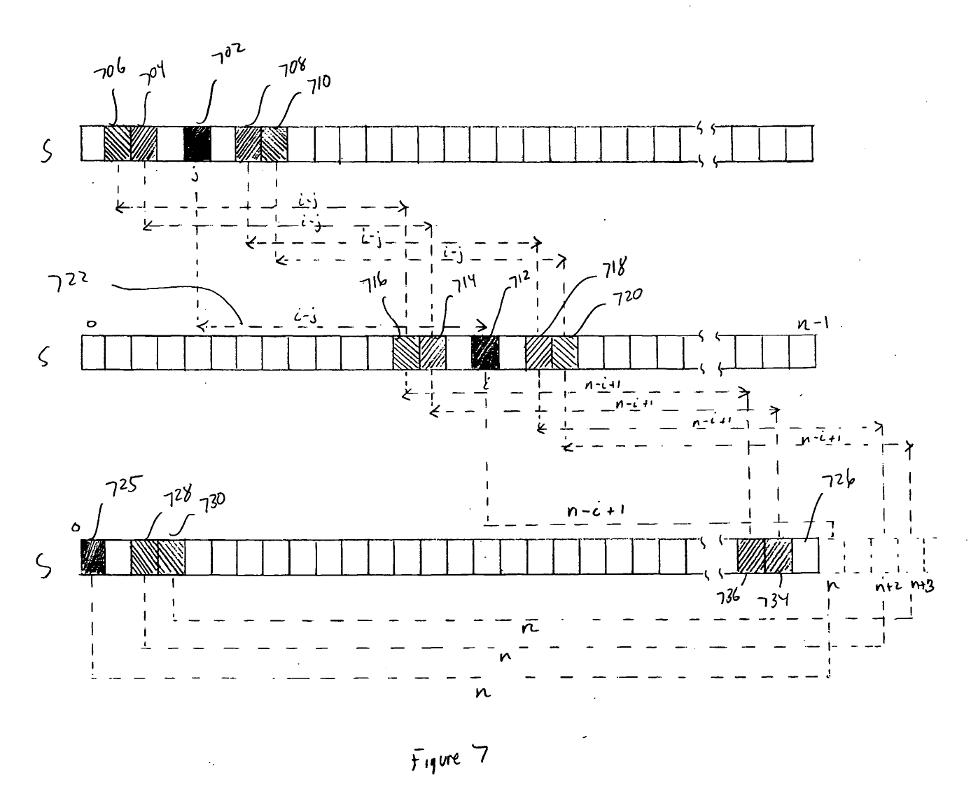

FIG. 7 illustrates neighbor pairs. The l^{th}-order neighborhood structure with respect to a symbol-sequence position i comprises the set of relative symbol-sequence indices, with respect to position i, of all positions in the l^{th}-order neighborhood of position i. In FIG. 7, the l^{th}-order neighborhood structure of position j 702 includes positions j−2 704, j−3 706, j+2 708, and j+3 710. Position i 712 can be seen in FIG. 7 to have the same neighborhood structure as position 702, since the l^{th}-order neighborhood of position i includes positions i−2 714, i−3 716, i+2 718, and i+3 720. In other words, if the distance, in symbol positions, between position j and position i is computed as i−j 722, then, if position i has the same neighborhood structure as position j, for each position k in the l^{th}-order neighborhood of position j, there is a corresponding position in the l^{th}-order neighborhood position i at a location k+i−j. Moreover, for each position p in the l^{th}-order neighborhood of position i, there is a neighborhood position in the l^{th}-order neighborhood of position j at location p−(i−j).

As also shown in FIG. 7, modular arithmetic may be used to circularize a linear symbol sequence in order to avoid special considerations for initial and final portions of the symbol sequence. Thus, position 725 shown in FIG. 7 has the same l^{th}-order neighborhood structure as positions 712 and 702 when the symbol string S is considered to be circular, with position 726 considered as the position prior to position 725. Thus, positions 728 and 730 have the same relative positions with respect to position 725 as positions 718 and 720 have with respect to position 712 and position 708 and 710 have with respect to 702. Similarly, positions 734 and 736 have the same relative positions, with respect to position 725, as have positions 714 and 716 with respect to position 712 and 704 and 706 with respect to position 702. In more concise notation:

In a symbol sequence S, with |S|=n,

Nₗ(i)=Nₗ(j) when

∀k:k ε Nₗ(i), (k+i−j) MOD n ε Nₗ(j);AND

∀p:p ε Nₗ(j), (p+i−j) MOD n ε Nₗ(i)

### Neighborhood-Based Statistics Acquisition

FIGS. 8 and 9 illustrate the general denoising method to which method embodiments of the present invention are directed and used by system embodiments of the present invention. FIG. 8 illustrates a first pass of the general method of the present invention for denoising a noisy signal. In the first pass, as shown in FIG. 8, statistics are collected for each symbol in the noisy sequence. FIG. 8 illustrates collection of statistics for the third symbol 804 of the noisy sequence Z 802. The third symbol in noisy sequence Z is the symbol “a₃.” The alphabet, in the example shown in FIG. 8, comprises the four symbols “a₁,” “a₂,” “a₃,” and “a₄.” In the example shown in FIG. 8, the neighborhood structure of each symbol marked by the notation “nₗ” is identical, and comprises the four symbols closest to the symbol in the sequence, two with indices greater than the index of the neighborhood-defining position, and two with indices less than the index of the neighborhood-defining position. In FIG. 8, the neighborhood 806 of the third symbol 804 is shown, along with the third symbol, above the noisy-symbol sequence Z.

Statistics are gathered for a currently considered symbol (in the current example, symbol 804) from other symbols in the noisy-symbol sequence Z that have the same neighborhood structure and the same configuration of noisy symbols in that neighborhood structure. The neighborhood structure may be defined as an l^{th}-order neighborhood according to appropriate application of neighborhood rules, as discussed above. In FIG. 8, the notation nᵢ, where i ε {0, 1, . . . ,9}, shown above each symbol of the noisy sequence indicates the neighborhood structure for that symbol. The neighborhood-structure symbol nₗ 808 associated with of the third symbol 804 of noisy-symbol sequence Z is shown circled in FIG. 8. In FIG. 8, all other symbols in the illustrated portion of noisy symbol-sequence Z with neighborhood structure nₗ are also shown within circles. Thus, noisy-symbol-sequence symbols 809-815 all share the same neighborhood structure, nₗ, with the third symbol 804. These seven additional symbols 809-815 are candidates for statistics acquisition during first-pass analysis of the third symbol 804. However, statistics for the currently considered symbol are acquired from symbols of the noisy symbol-sequence Z that both share the same neighborhood structure as that of the currently considered symbol as well as that have the same symbol configuration within the neighborhood structure as the symbol configuration within the neighborhood structure of the considered symbol. Examining the contents of the neighborhoods for the seven additional symbols of noisy symbol-sequence Z that share the same neighborhood structure as the third, currently considered symbol 804, it is easily determined that only symbols 811, 812, and 814 have both the same neighborhood structure and the same symbol configuration within that neighborhood structure as the third, currently considered symbol 804.

Each symbol Z_{c} is associated with a count vector \vec{N}_{(c)} with size |\vec{N}_{(c)}| equal to k, where k=|A|. In FIG. 8, the count vector 820 associated with the third symbol 804 is shown in the top portion of the figure, above both the representation of the noisy symbol-sequence Z and the neighborhood configurations of all of the symbols in the same neighborhood structure as the third, currently considered symbol 804. For each symbol, including the currently considered symbol, having the same neighborhood structure and same neighborhood-structure configuration as that of the currently considered symbol, the element of \vec{N}_{(c)} corresponding to the value of the symbol is incremented. In FIG. 8, as discussed above, there are four symbols 804, 811, 812, and 814 that share the same neighborhood structure and neighborhood-structure configuration as the currently considered symbol 804. Thus, the count in the count vector \vec{N}_{(c)} associated with each of the values of symbols 804, 811, 812, and 814 is incremented. These symbol values are, in order, “a₃,” “a₂,” “a₁,” and “a₄.” Thus, the originally zeroed count vector \vec{N}_{(c)} is updated for the displayed portion of the noisy symbol-sequence Z, during the statistics-analysis phase of the general denoising method of the present invention, as follows:

\vec{N}_{(c)}[a₃]++;

\vec{N}_{(c)}[a₂]++;

\vec{N}_{(c)}[a₁]++;

\vec{N}_{(c)}[a₄]++;

Since there is a single occurrence of each of the symbol values as the central symbol within the four neighborhoods of identical structure and configuration 806, 822, 823, and 824, the count vector associated with currently considered symbol Z₃, \vec{N}₍₃₎, has the count value “1” in each element. In general, in practical situations, count vectors generally end up containing a distribution of different count values reflective of correlations between the symbol contents of neighborhoods and the symbols of the corresponding neighborhood-defining positions.

It should be noted that a neighborhood rule needs to be applied to each symbol in the noisy-symbol sequence. In the case that the neighborhood rule encodes computation of an l^{th}-order neighborhood, where l is greater than 1, and where more than a single first-order neighborhood rule may be applicable at any neighborhood-order level from l to 1, any two, given positions within the noisy symbol-sequence Z, i and j may have different neighborhood structures.

After each symbol within a noisy symbol-sequence Z is separately considered in the first pass of the general method that represents one embodiment of the present invention, a count vector has been associated with each noisy-sequence symbol. FIG. 9 illustrates the results of the first pass of the general denoising method of the present invention. As shown in FIG. 9, each noisy-symbol-sequence symbol at a position c within the noisy symbol-sequence Z, such as symbol 902, is associated with a count vector \vec{N}_{(c)}, such as count vector 904, shown as a column vector beneath noisy-symbol-sequence symbol 902.

In alternative embodiments of the present invention, count vectors may be associated with groups of symbols, rather than, or in addition to, individual symbols, and statistics may be therefore collected for symbol groups, rather than, or in addition to, individual symbols.

In a second pass of the general denoising method that represents an embodiment of the present invention, a denoising rule is applied to each noisy-symbol-sequence symbol, and associated count vector, to produce a cleaned symbol value corresponding to the noisy-symbol-sequence symbol:

\hat{X}_{c}=D(Z_{c}, N_{(c)})

where D is a denoising rule. Many different denoising rules may be applied to noisy-symbol-sequence symbols, and associated count vectors, to generate corresponding denoised symbols. As discussed above, the alphabet from which denoised-signal symbols are selected may be the same as, or different from, the alphabet from which noisy-signal symbols are selected. In addition, in certain problem domains, a single denoised-signal symbol may be generated from two or more noisy-signal symbols and multiple denoised-signal symbols may be generated from a single noisy-signal symbol. In addition to a noisy-symbol-sequence symbol and corresponding count vector, a denoising rule may also use additional information about the noisy-symbol-sequence Z and about the original clean sequence X. In problem domains in which stochastically modeled noise corruption is introduced in a probabilistically modeled channel, and in which joint probability distributions for the occurrences of particular noisy-signal symbols in place of particular clean-signal symbols in each of various possible noisy-signal neighborhoods are hypothesized or computed, the denoising rule may compute, based on the joint probability distributions, the expected value of the cleaned-signal symbol \hat{X}ᵢ:

\hat{X}ᵢ=E(Xᵢ|Zᵢ, \vec{N}₍ᵢ₎)

Alternatively, a denoising rule may simply comprise a straightforward algorithm or mathematical formula entirely based on the supplied symbol and associated count vector. An example of a denoising rule that uses additional information is that of a class of discrete universal denoisers that rely on the probabilities of symbol corruption associated with a noise-inducing process, medium, or device, as well as loss functions that quantify the distortion produced by replacing noisy-symbol-sequence symbols with substitute symbols in the denoised symbol sequence corresponding to the noisy-symbol sequence. An example of a simply, algorithmic denoising rule is a majority-vote denoising rule for a binary symmetric channel (“BSC”) with a crossover probability 0≧δ<½:

$$D ( {Z}_{i} , \vec{N} ) = \{ \begin{matrix}0 & when {\vec{N}}_{( 0 )} \geq {\vec{N}}_{( 1 )} \\ 1 & otherwise\end{matrix}$$

In alternative embodiments of the present invention, demising rules may be applied to groups of symbols, rather than, or in addition to, individual symbols, and replacement symbols or groups of replacement symbols may be therefore generated for symbol groups, rather than, or in addition to, individual symbols.

### C++-Like Pseudocode Embodiment

Next, a relatively straightforward, C++-like pseudocode embodiment of the present invention is provided. This pseudocode is not intended to in any way define the present invention or limit the scope of the present invention, but merely to illustrate one approach for implementing a general denoiser according to the present invention.

First, the number of constants and type declarations are provided:
1 const int K=10;
2 const int maxNeighborhoodSz=5;
3 const int maxN=1000;
4 const int maxOrder=7;
5 typedef int COUNT_VECTOR[K];
6 typedef int (*denoisingRule)(int* c, int z);
   The constant K is the alphabet size, as well as the size of count vectors. The constant maxNeighborhoodSz, declared above on line 2, is the maximum number of positions within any neighborhood structure for a position of a noisy symbol sequence. The constant maxN, declared above on line 3, is the maximum length of a noisy symbol sequence. The constant maxOrder, declared above on line 4, is the maximum neighborhood order that can be specified. The type COUNT_VECTOR, declared above on line 5, represents a count vector for collection of statistics for a single symbol in a noisy symbol sequence. The type “denoisingRule,” declared above on line 6, is a reference type for a denoising-rule function that is supplied to a denoising method of the present invention.

Next, a simple neighborhood class is provided:

```
  1 class neighborhood
  2 {
  3  private:
  4  int indices[maxNeighborhoodSz];
  5  int size;
  6
  7  public:
  8  int* wrap(int* start, int* i, int sz);
  9  void enter(int relIndex);
10  void clear( ) {size = 0;};
11  int getRelIndex(int i)
12  {if (i < size && i >= 0) return indices[i]; else return 0;};
13  int getSize( ) {return size;};
14  bool equalNConfig(int* start, int* i, int* j, int sz);
15  bool equalNStructure(neighborhood* n);
16  neighborhood( );
17 };
```

The relative indices that define the neighborhood are stored in a private data-member array “indices,” declared on line 4. The private data member “size,” declared on line 5, indicates the number of relative indices within the definition of the neighborhood stored in the private data member “indices.” The class “neighborhood” includes, in addition to a constructor, the following public function members declared above on lines 8-15: (1) wrap, a function that carried out modular arithmetic on a symbol position to circularize a linear symbol sequence; (2) enter, a function that enters a relative index into private-data-member “indices;” (3) clear, a function that re-initializes an instance of class “neighborhood;” (4) getRelIndex, a function that returns the element of private data member “indices” at a specified position; (5) getSize, a function that returns the number of relative indices in the private data member “indices;” (6) equalNConfig, a function that determines whether the neighborhood of a first symbol has the same symbol configuration as the neighborhood of another specified symbol; and (7) equalNStructure, a function that determines whether an instance of the class “neighborhood” has the same neighborhood structure as a specified instance of the class “neighborhood.”

Next, a type declaration for a neighborhood rule is provided:
1 typedef void (*neighborhoodRule)(int* start, int*i, int sz,
2 neighborhood* n, int order);

Next, a denoiser class is provided:

```
  1 class denoiser
  2 {
  3  private:
  4  COUNT_VECTOR countVs[maxN];
  5  denoisingRule dRule;
  6  neighborhoodRule nRule;
  7  int order;
  8
  9  public:
10  void denoise(int* z, int n, int* xHat);
11  denoiser(int order, denoisingRule dR, neighborhoodRule nR);
12 };
```

The class “denoiser” includes count vectors for up to maxN symbols of a noisy symbol sequence, countVs, declared on line 4, references to a denoising rule and a neighborhood rule, “dRule,” and “nRule,” respectively, declared on lines 5 and 6, and an integer order that contains the neighborhood order to compute for symbols during the first pass of a denoising method that represents an embodiment of the present invention. In addition to a constructor, the class “denoiser” includes the function member “denoise,” declared on line 11, above, which denoises a supplied noisy symbol sequence to produce a cleaned symbol sequence.

Implementations for the function members of the class “neighborhood” are next provided. First, the function member “wrap” is provided:

1 int* neighborhood::wrap(int* start, int* i, int sz)
2 {
3 if (i < start) i += sz;
4 else if (i >= start + sz) i −= sz;
5 return i;
6 }

The function member “wrap” determines whether or not a supplied reference to a symbol, i, is outside the bounds of a symbol sequence with initial symbol referenced by argument “start” and final symbol referenced by start+sz−1. If i is outside the valid positions of symbols, the function wrap adjusts i via modular arithmetic to reference a position within the symbol sequence, essentially circularizing the symbol sequence.

First, the function member “enter” is provided:

1 void neighborhood::enter(int relIndex)
2 {
3 int p;
4
5 if (size == maxNeighborhoodSz) return;
6 for (p = 0; p < size; p++) if (indices[p] == relIndex) return;
7 indices[size++] = relIndex;
8 }

The function member “wrap” determines whether or not a supplied reference to a symbol, i, is outside the bounds of a symbol sequence with initial symbol referenced by argument “start” and final symbol referenced by start+sz−1. If i is outside the valid positions of symbols, the function wrap adjusts i via modular arithmetic to reference a position within the symbol sequence, essentially circularizing the symbol sequence.

Next, the function member “equalNStructure” is provided:

```
  1 bool neighborhood::equalNStructure(neighborhood* n)
  2 {
  3  int p, q;
  4  int nxt;
  5  bool res;
  6
  7  if (n->getSize( ) != size) return false;
  8  for (p = 0; p < size; p++)
  9  {
10  nxt = n->getRelIndex(p);
11  res = false;
12  for (q = 0; q < size; q++)
13  {
14  if (nxt == indices[q])
15  {
16  res = true;
17  break;
18  }
19  }
20  if (!res) return false;
21  }
22  return true;
23 }
```

The function member “equalNStructure” determines whether or not a supplied reference to an instance of the neighborhood class, n, has the same structure as the instance of the neighborhood class called through function member “equalNStructure.” On line 7, FALSE is returned if the number of relative indices is different in the two classes. Otherwise, in the nested for-loops of lines 8-21, the contents of the data-member arrays “indices” are compared for the two instances of the class “neighborhood.” The value FALSE is returned when the contents of the two arrays differ, and TRUE is returned when the contents of the two arrays are the same. The ordering of the relative indices in the two arrays is not significant.

Next, the function member “equalNConfig” is provided:

```
  1 bool neighborhood::equalNConfig(int* start, int* i, int* j, int sz)
  2 {
  3
  4  int p;
  5  int* nxtI;
  6  int* nxtJ;
  7  bool res = true;
  8
  9  for (p = 0; p < size; p++)
10  {
11  nxtI = wrap(start, indices[p] + i, sz);
12  nxtJ = wrap(start, indices[p] + j, sz);
13  if (*nxtI != *nxtJ)
14  {
15  res = false;
16  break;
17  }
18  }
19  return res;
20 }
```

The function member “equalNConfig” determines whether or not the configurations of neighborhoods represented by an instance of the class “neighborhood,” about two neighborhood-defining positions, are identical. In the for-loop of lines 9-19, each symbol in the neighborhood of the symbol referenced by supplied symbol-reference i is compared to the corresponding symbol in the neighborhood of the symbol referenced by supplied symbol-reference j. When all symbols of the two, respective neighborhood are equal, TRUE is returned. Otherwise, FALSE is returned.

Finally, a constructor is provided, without additional annotation:

1 neighborhood::neighborhood( )
2 {
3 size = 0;
4 }

Next, an implementation of the function members of class “denoiser” are provided: First, the function-member “denoise” is provided:

```
  1 void denoiser::denoise(int* z, int n, int* xHat)
  2 {
  3  int i, j;
  4  int nxt;
  5  neighborhood ni, nj;
  6
  7  for (i = 0; i < n; i++)
  8  {
  9  nRule(z, z + i, n, &ni, order);
10  for (j = 0; j < n; j++)
11  {
12  if (j != i)
13  {
14  nRule(z, z + j, n, &nj, order);
15  if (ni.equalNStructure(&nj) && nj.equalNConfig(z,
z + i, z + j, n))
16  {
17  nxt = *(z +j);
18  if (nxt < 0) nxt = 0;
19  if (nxt >= K) nxt = K − 1;
20  countVs[i][nxt]++;
21  }
22  }
23  }
24  }
25  for (i = 0; i < n; i++)
26  {
27  *(xHat + i) = dRule(&(countVs[i][0]), *(z + i));
28  }
29 }
```

The outerfor-loop of lines 24 implement the first pass of a general denoising method that represents one embodiment of the present invention. In this outerfor-loop, each symbol of a noisy symbol sequence is considered, in turn. In the inner for-loop of lines 12-22, the neighborhood of the currently considered symbol with respect to the outerfor-loop is compared to the neighborhood of all other symbols, and, when the neighborhood of the currently considered symbol has the same configuration and structure as that of a currently considered symbol with respect to the inner for-loop, the count vector for the currently considered symbol is updated, as discussed above with reference to FIG. 8. The for-loop of lines 25-28 implement the second pass of a general denoising method that represents one embodiment of the present invention.

A constructor for the class “denoiser” is provided, with minimal annotation:

```
  1 denoiser::denoiser(int ord, denoisingRule dR, neighborhoodRule nR)
  2 {
  3  int i, j;
  4
  5  if (ord >= 1 && ord <= maxOrder) order = ord;
  6  else ord = 1;
  7  nRule = nR;
  8  dRule = dR;
  9  for (i = 0; i < maxN; i++)
10  {
11  for (j = 0; j < K; j++) countVs[i][j] = 0;
12  }
13 }
```

Finally, a simple denoising rule, a simple neighborhood rule, and an example main function are provided:

```
  1 int dRule(int* c, int z)
  2 {
  3  int i;
  4  int j = 0;
  5  int n = 0;
  6
  7  for (i = 0; i < K; i++)
  8  {
  9  if (c[i] > n)
10  {
11  n = c[i];
12  j = i;
13  }
14  }
15  return j;
16 }
```

The above denoising rule selects, as the replacement symbol, the symbol that occurs at highest frequency in the neighborhood of a noisy-symbol-sequence symbol.

```
  1 void nRule(int* start, int* i, int sz, neighborhood* n, int order)
  2 {
  3  int j, k, m, sZ;
  4  int* nxt;
  5  neighborhood tmp;
  6
  7  n->clear( );
  8  if (*i % 2)
  9  {
10  n->enter(−1);
11  n->enter(1);
12  }
13  else
14  {
15  n->enter(−2);
16  n->enter(−1);
17  n->enter(1);
18  n->enter(2);
19  }
20  for (j = 1; j < order; j++)
21  {
22  sZ = n->getSize( );
23  for (k = 0; k < sZ; k++)
24  {
25  nxt = n->wrap(start, n->getRelIndex(k) + i, sz);
26  nRule(start, nxt, sz, &tmp, 1);
27  for (m = 0; m < tmp.getSize( ); m++)
28  {
29  n->enter(tmp.getRelIndex(m));
30  }
31
32  }
33  }
34 }
```

The above neighborhood rule selects generates two different types of neighborhoods, depending on the parity of the symbol location.

```
  1 int main(int argc, char* argv[ ])
  2 {
  3
  4  int z[30] = {1, 2, 3, 4, 5, 5, 4, 3, 2, 1, 1, 2, 3, 4, 5,
  5  5, 4, 3, 2, 1, 1, 2, 3, 4, 5, 5, 4, 3, 2, 1};
  6  int x[30];
  7
  8  denoiser d(2, dRule, nRule);
  9  d.denoise(z, 30, x);
10 return 0;
11 }
```

### Applications to Particular Problem Domains

The general denoising method to which method embodiments of the present invention are directed provides an algorithmic framework for a wide variety of different specific denoising method embodiments of the present invention. For example, Low Density Parity Check codes (“LDPC”) may be decoded using appropriate LDPC-based denoising rules and neighborhood-rules derived from the Tanner graph of the LDPC code. In this example, a neighborhood may comprise symbol positions corresponding to columns of the parity matrix related by Tanner-graph edges to identical parity-matrix rows.

The method embodiments of the present invention need not employ information about the noise-inducing characteristics of a noise-inducing medium, process, or device, but can employ such information, when available, through the denoising rule. The method embodiments of the present invention can be used for symbol-sequence alphabets of arbitrary cardinality. The computational complexity and performance of method embodiments of the present invention may match or exceed those of other, currently available methods, including belief-propagation decoding. Finally, because of the wide variety of different types of neighborhood rules that can be applied, method embodiments of the present invention may be used for denoising symbol sequences with higher levels of organization, including two-dimensional images, linearly-specified information three-dimensional structure, and higher-dimensional information.

### Conclusion

Although the present invention has been described in terms of particular embodiments, it is not intended that the invention be limited to these embodiments. Modifications within the spirit of the invention will be apparent to those skilled in the art. For example, a large number of different embodiments of the present invention can be implemented using different programming languages, control structures, modular organizations, data structures, and by varying other such programming parameters. System embodiments of the present invention include computer systems and other electronic devices that include one or more processors, memory, and stored neighborhood-generation and denoising rules that can be applied by software or firmware that implements a method embodiment of the present invention. As discussed above, the general denoising method of the present invention, and denoising systems that incorporate the denoising methods of the present invention, are supplied neighborhood-generation routines and denoising rules in order to carry out the denoising process. Neighborhood rules may be of any order, as discussed above, and may generate from one to N−1 symbols for a neighborhood-defining position within a noisy-symbol sequence containing N symbols. As discussed above, a wide variety of different denoising rules may be applied in different problem domains, some relying only on supplied noisy-symbol-sequence symbol and associated count vector, while others rely on additional information about the noise-inducing process, medium, or device that introduces noise into the noisy symbol sequence and information about the original, clean symbol sequence. The above-described method can be incorporated into a wide variety of different devices and processes used for data transmission and data processing, including mass-storage-device controllers, communications controllers, printers and scanners, data-analysis software and systems, and many other devices and process. In certain embodiments, it may be more computationally efficient to generate neighborhoods, by application of a neighborhood rule, for each nosy-symbol-sequence symbol, rather than recomputing neighborhoods during each iteration of the first-pass traversal of the noisy symbol sequence. As discussed above, while certain embodiments of the present invention assume closed symbol transformations and that the cleaned signal produced by denoising has the same length as the received noisy symbol sequence, these constraints may be somewhat relaxed, in certain embodiments of the present invention. In addition, while neighborhood equivalence, for identifying symbols from which to collect statistics, is described, in the above-discussed embodiment, as requiring two neighborhoods to have identical configurations and structures, the equivalence criteria may also be relaxed, in certain embodiments of the present invention, to allow a larger set of symbols to be used for statistics collection with respect to any given, currently considered symbol in the noisy symbol sequence.

The foregoing description, for purposes of explanation, used specific nomenclature to provide a thorough understanding of the invention. However, it will be apparent to one skilled in the art that the specific details are not required in order to practice the invention. The foregoing descriptions of specific embodiments of the present invention are presented for purpose of illustration and description. They are not intended to be exhaustive or to limit the invention to the precise forms disclosed. Many modifications and variations are possible in view of the above teachings. The embodiments are shown and described in order to best explain the principles of the invention and its practical applications, to thereby enable others skilled in the art to best utilize the invention and various embodiments with various modifications as are suited to the particular use contemplated. It is intended that the scope of the invention be defined by the following claims and their equivalents:

1. A method for reconstructing a noise-corrupted signal to produce a cleaned signal, the method comprising:
receiving the noise-corrupted signal, a denoising rule, and a neighborhood rule;
in a fist pass,
applying the neighborhood rule to each noise-corrupted-signal component to generate a neighborhood for the noise-corrupted-signal component and collecting statistics for the noise-corrupted-signal component based on other noise-corrupted-signal components with equivalent neighborhoods; and
in a second pass,
applying the denoising rule to each noise-corrupted-signal component, using statistics collected for the symbol in the first pass, to generate a corresponding cleaned-signal component.

2. The method of claim 1
wherein the noise-corrupted signal and the cleaned signal are both ordered sequences of symbols;
wherein each noise-corrupted-signal symbol is selected from an alphabet of symbols A₁ of cardinality |A₁|=k and each cleaned-signal symbol is selected from an alphabet of symbols A₂ of cardinality |A₁|=m, and
wherein each noise-corrupted signal component and cleaned-signal component comprises one or more symbols.

3. The method of claim 1 wherein a noise-corrupted-signal-component neighborhood comprises one or more additional noise-corrupted-signal components selected from the noise-corrupted signal.

4. The method of claim 3 wherein the neighborhood rule that specifies the one or more additional noise-corrupted-signal components selected from the noise-corrupted signal comprises one or more of:
a list of neighborhood-defining position relative to a neighborhood-defining noise-corrupted-signal-component positions; and
a computational method for computing noise-corrupted-signal-component positions relative to a neighborhood-defining noise-corrupted-signal-component position.

5. The method of claim 4 wherein a neighborhood may be specified as an l^{th}-order neighborhood, the noise-corrupted-signal-component positions of the l^{th}-order neighborhood obtained by:
applying the neighborhood rule to generate a set of noise-corrupted-signal-component positions; and
successively applying the neighborhood rule, l−1 times, to the set of noise-corrupted-signal-component positions to generate additional noise-corrupted-signal-component positions that are added to the set of noise-corrupted-signal-component positions.

6. The method of claim 4 wherein a first neighborhood of a first neighborhood-defining position is equivalent to a second neighborhood of a second neighborhood-defining position when the first and second neighborhoods are comprised of identical sets of relative noise-corrupted-signal-component positions and, for each relative noise-corrupted-signal-component position, a noise-corrupted-signal-component of the same type occurs at the relative noise-corrupted-signal-component position with respect to the first and second neighborhood-defining positions.

7. The method of claim 1
wherein a count vector is associated with each noise-corrupted-signal component, the count vector containing a count for every possible type of noise-corrupted-signal component; and
wherein collecting statistics for a currently considered noise-corrupted-signal component based on other noise-corrupted-signal components with equivalent neighborhoods further comprises, for each other noise-corrupted-signal component with a neighborhood equivalent to the neighborhood of the currently considered noise-corrupted-signal component, incrementing the count-vector count corresponding to the type of the other noise-corrupted-signal component.

8. The method of claim 1 included in a process or device to produce a denoising system, the process or device including:
a computer system;
a data transmitter;
a data receiver;
a printer;
a scanner; and
a communications controller.

9. The method of claim 1 wherein the noise-corrupted signal is corrupted by one or more of:
transmission through a communications medium;
storage within a signal-storing device; and
processing by a signal-processing system.

10. A system that reconstructs a noise-corrupted signal to produce a cleaned signal, the system comprising:
a processor that
receives a denoising rule,
receives a neighborhood rule,
in a fist pass,
applies the neighborhood rule to each noise-corrupted-signal component to generate a neighborhood for the noise-corrupted-signal component and collects statistics for the noise-corrupted-signal component based on other noise-corrupted-signal components with equivalent neighborhoods, and
in a second pass,
applies the denoising rule to each noise-corrupted-signal component, using statistics collected for the symbol in the first pass, to generate a corresponding cleaned-signal component that the processor.

11. The system of claim 10
wherein the noise-corrupted signal and the cleaned signal are both ordered sequences of symbols;
wherein each noise-corrupted-signal symbol is selected from an alphabet of symbols A₁ of cardinality |A₁|=k and each cleaned-signal symbol is selected from an alphabet of symbols A₂ of cardinality |A₁|=m, and
wherein each noise-corrupted signal component and cleaned-signal component comprises one or more symbols.

12. The system of claim 10 wherein a noise-corrupted-signal-component neighborhood comprises one or more additional noise-corrupted-signal components selected from the noise-corrupted signal.

13. The system of claim 12 wherein the neighborhood rule that specifies the one or more additional noise-corrupted-signal components selected from the noise-corrupted signal comprises one or more of:
a list of neighborhood-defining position relative to a neighborhood-defining noise-corrupted-signal-component positions; and
a computational method for computing noise-corrupted-signal-component positions relative to a neighborhood-defining noise-corrupted-signal-component position.

14. The system of claim 13 wherein a neighborhood may be specified as an l^{th}-order neighborhood, the noise-corrupted-signal-component positions of the l^{th}-order neighborhood obtained by:
applying the neighborhood rule to generate a set of noise-corrupted-signal-component positions; and
successively applying the neighborhood rule, l−1 times, to the set of noise-corrupted-signal-component positions to generate additional noise-corrupted-signal-component positions that are added to the set of noise-corrupted-signal-component positions.

15. The system of claim 13 wherein a first neighborhood of a first neighborhood-defining position is equivalent to a second neighborhood of a second neighborhood-defining position when the first and second neighborhoods are comprised of identical sets of relative noise-corrupted-signal-component positions and, for each relative noise-corrupted-signal-component position, a noise-corrupted-signal-component of the same type occurs at the relative noise-corrupted-signal-component position with respect to the first and second neighborhood-defining positions.

16. The system of claim 10
wherein a count vector is associated with each noise-corrupted-signal component, the count vector containing a count for every possible type of noise-corrupted-signal component; and
wherein collecting statistics for a currently considered noise-corrupted-signal component based on other noise-corrupted-signal components with equivalent neighborhoods further comprises, for each other noise-corrupted-signal component with a neighborhood equivalent to the neighborhood of the currently considered noise-corrupted-signal component, incrementing the count-vector count corresponding to the type of the other noise-corrupted-signal component.

17. The system of claim 10 wherein the noise-corrupted signal is corrupted by one or more of:
transmission through a communications medium;
storage within a signal-storing device; and
processing by a signal-processing system.
